(19) United States
(12) Patent Application Publication
(10) Pub. No.: US 2025/0248064 A1
(43) Pub. Date: Jul. 31, 2025

(54) Thermally Stable FinFET Device for High Temperature Operation

(71) Applicant: Wolfspeed, Inc., Durham, NC (US)

(72) Inventors: Fabian Radulescu, Chapel Hill, NC (US); Scott Sheppard, Chapel Hill, NC (US); Jia Guo, Apex, NC (US); Olof Tornblad, San Jose, CA (US); Michael Lee Schuette, Sunbury, OH (US)

(21) Appl. No.: 18/422,677

(22) Filed: Jan. 25, 2024

(51) Int. Cl. H01L 29/78; H01L 29/16; H01L 29/812

(52) U.S. Cl. CPC H10D 30/6211; H10D 30/873; H10D 62/8325; H10D 30/6218

(57) ABSTRACT

A semiconductor device is provided. The semiconductor device includes a semiconductor structure comprising silicon carbide. The semiconductor device further includes a mesa structure protruding in a first direction from the semiconductor structure, the mesa structure extending in a second direction between a first contact on the semiconductor structure and a second contact on the semiconductor structure. The semiconductor device further includes a channel region in the mesa structure. The semiconductor device further includes an electrically floating confining region, the electrically floating confining region in contact with the channel region in the mesa structure. The semiconductor device further includes a third contact on at least one sidewall of the mesa structure.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a semiconductor structure comprising silicon carbide. The semiconductor device further includes a mesa structure protruding in a first direction from the semiconductor structure, the mesa structure extending in a second direction between a first contact on the semiconductor structure and a second contact on the semiconductor structure. The semiconductor device further includes a channel region in the mesa structure. The semiconductor device further includes an electrically floating confining region, the electrically floating confining region in contact with the channel region in the mesa structure. The semiconductor device further includes a third contact on at least one sidewall of the mesa structure.

Another example aspect of the present disclosure is directed to a semiconductor device. The semiconductor device includes a semiconductor structure comprising silicon carbide. The semiconductor device further includes a source contact on the semiconductor structure. The semiconductor device further includes a drain contact on the semiconductor structure. The semiconductor device further includes a mesa structure protruding from the semiconductor structure, the mesa structure comprising silicon carbide, the mesa structure comprising a channel region and a confining region. The semiconductor device further includes a gate contact on the mesa structure.

Another example aspect of the present disclosure is directed to a lateral transistor device. The lateral transistor device includes a semiconductor structure comprising silicon carbide. The lateral transistor device further includes a mesa structure protruding from the semiconductor structure, the mesa structure comprising silicon carbide, the mesa structure comprising a channel region. The lateral transistor device further includes a gate contact on a top surface of the mesa structure and a sidewall of the mesa structure.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a semiconductor device according to example embodiments of the present disclosure;

FIG. 2 depicts a semiconductor device according to example embodiments of the present disclosure;

FIG. 3 depicts a semiconductor device according to example embodiments of the present disclosure;

FIG. 4 depicts a semiconductor device according to example embodiments of the present disclosure;

FIG. 5 depicts a semiconductor device according to example embodiments of the present disclosure;

FIG. 6 depicts a semiconductor device according to example embodiments of the present disclosure;

FIG. 7 depicts a semiconductor device according to example embodiments of the present disclosure;

FIGS. 8A-8B depict response characteristics of an example semiconductor device according to example embodiments of the present disclosure;

FIG. 9 depicts a block diagram of an example RF circuit incorporating semiconductor devices according to example embodiments of the present disclosure; and

FIG. 10 depicts a block diagram of an example RF circuit incorporating semiconductor devices according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Semiconductor devices, such as field effect transistors (FETs), may be used in power electronics applications. Transistor devices fabricated in Group III nitride-based material systems may have the potential to generate large amounts of radio frequency (RF) power because of the combination of material characteristics that includes high breakdown fields, wide bandgaps, large conduction band offset, and/or high saturated electron drift velocity. As such, Group III nitride based HEMTs may be promising candidates for high frequency and/or high-power RF applications, as well as for low frequency high power switching applications, both as discrete transistors or as coupled with other circuit elements. A fin field effect transistor (FinFET) is a special class of FETs built on a substrate where a “fin” structure or “mesa” structure extends between a source contact and drain contact, with a gate contact placed on the fin structure. FinFET devices are non-planar devices or “3D” devices due to the components extending above the surface of a substrate on which they are formed.

HEMT devices employ a heterojunction of two semiconductor materials with different bandgap energies, where the smaller bandgap material has a higher electron affinity. This heterojunction can contribute to reduced thermal dissipation properties and increased operating temperatures, especially at high frequencies. Aspects of the present disclosure are directed to semiconductor devices, such as silicon carbide (SiC) devices, that can provide 3D gate field modulation without making use of a heterojunction. In particular, a semiconductor device having a mesa structure (e.g., a fin structure) protruding from a semiconductor structure can include a channel region and a confining region in contact with the channel region in the mesa structure. The mesa structure can extend between a first contact on the semiconductor structure and a second contact on the semiconductor structure. A third contact can be on at least one sidewall of the mesa structure.

Aspects of the present disclosure provide a number of technical effects and benefits. For instance, a semiconductor device according to example aspects of the present disclosure can provide an improved thermal dissipation path and increase a maximum operating temperature (e.g., a junction temperature) of the semiconductor device. Silicon carbide has a thermal conductivity of more than ten times that of silicon. Accordingly, silicon carbide based FinFET devices can provide for improved thermal performance. Furthermore, the three-dimensional device geometry of the semiconductor device can provide improved suppression of short-channel effects and enhance performance, especially at high frequencies. For example, a FinFET structure utilizing exclusively silicon carbide-based materials can provide power amplifiers that operate at high frequencies and at high temperatures without significant disruption of performance. In addition, aspects of the present disclosure can provide operational FinFET devices without requiring high thermal resistance buffers (e.g., GaN buffers), simplifying manufacturing and reducing device cost. Furthermore, when provided in a power amplifier circuit, such as an RF amplifier circuit, semiconductor devices according to example aspects of the present disclosure can provide reduced operating costs associated with reduced cooling requirements and/or improved efficiency.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

As used herein, the term “generally perpendicular” refers to within 15° of perpendicular. As used herein, the term “generally parallel” refers to within 15° of parallel.

Aspects of the present disclosure are discussed with reference to a FinFET transistor device for purposes of illustration and discussion. Those of ordinary skill in the art, using the disclosures provided herein, will appreciate that certain aspects of the present disclosure may be applicable to other transistor devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

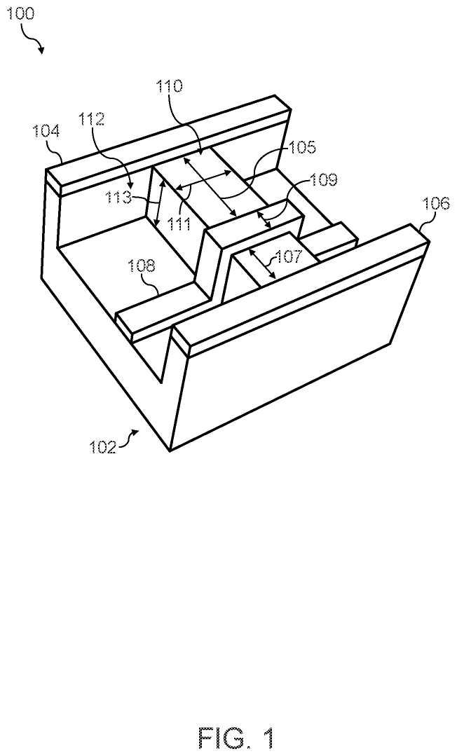

FIG. 1 depicts a semiconductor device 100 according to example embodiments of the present disclosure. The semiconductor device 100 can be, for example, a field effect transistor such as a FinFET device (e.g., a MOSFET type FinFET device, a MESFET type FinFET device etc.), or other suitable transistor device. In some implementations, the semiconductor device 100 can be a lateral transistor device. The lateral transistor device can provide a gate contact, a source contact, and a drain contact on a same surface of the semiconductor device 100. The semiconductor device 100 can include a semiconductor structure 102, such as a semiconductor substrate. The semiconductor structure 102 can include or be formed of silicon carbide (SiC) or another suitable semiconductor material. In some implementations, the semiconductor structure 102 can be a semi-insulating silicon carbide substrate.

The semiconductor device 100 can include a mesa structure 110 protruding in a first direction from the semiconductor structure 102. The mesa structure 110 can be formed of a common material with the semiconductor structure 102. For instance, in some implementations, the mesa structure 110 can include silicon carbide. The mesa structure 110 can be a portion of an epitaxial layer. For instance, the epitaxial layer can be grown on the semiconductor structure 102 in a separate manufacturing step for the creation of the semiconductor structure 102. In some implementations, the mesa structure 110 can be formed by etching the semiconductor structure 102. One or more recesses 112 can be on either side of the mesa structure 110. The recesses 112 can isolate the mesa structure 110. Although only a single mesa structure 110 is illustrated in FIG. 1 for the purposes of illustration, it should be understood that the semiconductor device can include a plurality of mesa structures 110, where each mesa structure 110 is separated from an adjacent mesa structure 110 by a recess 112.

The mesa structure 110 can extend in a second direction between a first contact 104 on the semiconductor structure 102 and a second contact 106 on the semiconductor structure 102. The first contact 104 can be a drain contact, such as a contact forming a drain of the semiconductor device 100. Additionally or alternatively, the second contact 106 can be a source contact, such as a contact forming a source of the semiconductor device 100. A third contact 108 can be on at least one sidewall of the mesa structure 110. The third contact 108 can be a gate contact, such as a contact forming a gate of the semiconductor device 100. For instance, the mesa structure 110 can provide an electrically conductive channel based on a voltage applied to the third contact 108.

The third contact 108 can be between the first contact 104 and the second contact 106 (e.g., along the second direction). The third contact 108 can be positioned at a first distance 105 from the first contact 104 and a second distance 107 from the second contact 106. The first distance 105 can be different from the second distance 107. For instance, in some implementations, the first distance 105 can be in a range of about 0.3 μm to about 0.5 μm, such as a range of about 0.35 μm to about 0.45 μm, such as about 0.4 μm, or any other suitable distance. Additionally or alternatively, in some implementations, the second distance 107 can be in a range of about 0.1 μm to about 0.3 μm, such as about 0.15 μm to about 0.25 μm, such as about 0.2 μm, or any other suitable distance. In addition, the third contact 108 can have a width dimension 109 defined along the second direction. The width dimension 109 can be any suitable dimension. For instance, in some implementations, the width dimension 109 can be in a range of about 0.05 μm to about 0.15 μm, such as from about 0.08 μm to about 0.12 μm, such as about 0.1 μm, or any other suitable dimension. A length dimension of the mesa structure 110 can be defined by the combination (e.g., sum) of the first distance 105, the second distance 107, and the width dimension 109 of the third contact 108.

In some implementations, the semiconductor device 100 can be a lateral transistor device such that the first contact 104, the second contact 106, and the third contact 108 are each positioned on a same side of the semiconductor structure 102. For instance, each of the first contact 104, the second contact 106, and the third contact 108 can be positioned on a same side of the semiconductor structure 102 as the mesa structure 110. As another example, there may not be a source contact, a gate contact, or a drain contact on an opposite side of the semiconductor structure 102 from the side of the semiconductor structure 102 including the mesa structure 110.

In some implementations, the first contact 104 and/or the second contact 106 can be an ohmic contact with the semiconductor structure 102. For instance, the first contact 104 and/or the second contact 106 can have a relationship between resistivity and voltage that is linear in nature (e.g., similar to a resistor or resistive element). Additionally or alternatively, in some implementations, the third contact 108 can be a Schottky contact with the mesa structure 110. For instance, the third contact 108 can have rectifying behavior similar to Schottky diodes with the mesa structure 110. As one example, the third contact 108 may be made of a suitable metal in direct contact with the semiconductor (e.g., SiC) of the mesa structure 110 to form a Schottky barrier.

The mesa structure 110 can additionally include a width dimension 111 and a height dimension 113. The width dimension 111 can be generally perpendicular to a direction of the mesa structure 110 between the first contact 104 and the second contact 106 (e.g., the second direction in which the mesa structure 110 extends) in a plane that is generally parallel to the semiconductor structure 102. In some implementations, the width dimension 111 is in a range of about 10 nm to about 5000 nm, such as about 50 nm to about 1000 nm, such as about 150 nm to about 350 nm, such as about 200 nm to about 300 nm. In addition, the height dimension 113 can be generally perpendicular to the semiconductor structure 102 (e.g., to a plane generally parallel to the semiconductor structure 102. In some implementations, the height dimension 113 is in a range of about 50 nm to about 5000 nm, such as about 50 nm to about 1000 nm, such as about 150 nm to about 350 nm, such as about 200 nm to about 300 nm.

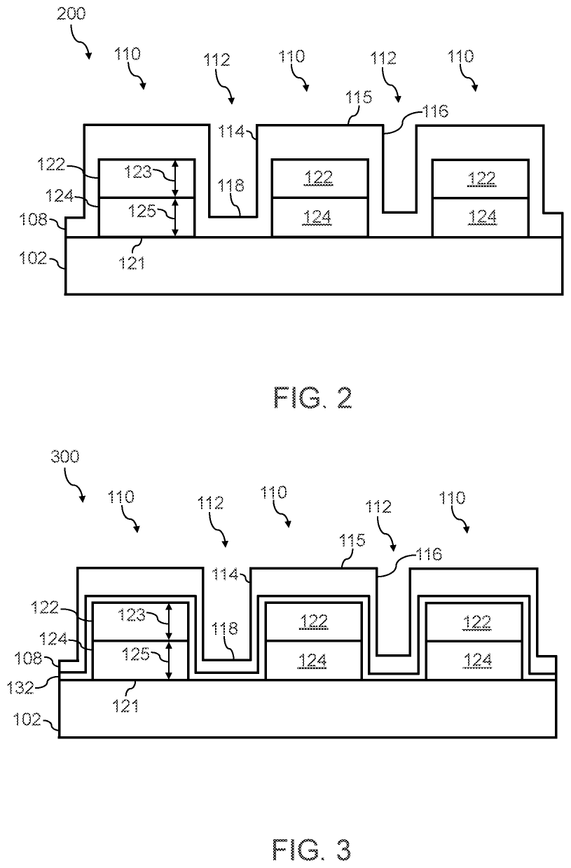

FIG. 2 depicts a cross-sectional view of a semiconductor device 200 according to example embodiments of the present disclosure. The semiconductor device 200 includes various components discussed with reference to FIG. 1, including the semiconductor structure 102, a plurality of mesa structures 110, a plurality of recesses 112 defined between the plurality of mesa structures 110, and the third contact 108 (e.g., a gate contact). Except where otherwise indicated, these like reference numerals are used to represent like components, and description with respect to the semiconductor device 100 of FIG. 1 is equally intended to apply to the semiconductor device 200 of FIG. 2.

The mesa structure 110 of the semiconductor device 200 includes a channel region 122 (e.g., a first region). The channel region 122 can provide an electrically conductive channel between the first contact 104 (FIG. 1) and the second contact 106 (FIG. 1) based on a voltage applied to the third contact 108. For instance, the channel region 122 can provide for electrons to flow between the first contact 104 and the second contact 106 through the mesa structure 110, within the channel region 122, based on the voltage applied to the third contact 108. The channel region 122 may be configured for either depletion mode type semiconductor devices or enhancement mode type semiconductor devices, depending on whether the electrically conductive channel is provided or not at neutral voltage.

Additionally, the mesa structure 110 can include a confining region 124 (e.g., a second region) in contact with the channel region 122 in the mesa structure 110. The confining region 124 can prevent the flow of electrons within or through the confining region 124 (e.g., into the semiconductor structure 102), thereby limiting the flow of electrons to be within the channel region 122. In some implementations, the confining region 124 may be an electrically floating confining region. For instance, the electrically floating confining region may not be grounded or coupled to an external voltage neutral or ground.

The channel region 122 can have a first conductivity type. For instance, in some implementations, the channel region 122 is n-type. The channel region 122 can be doped with suitable dopants to form the first conductivity type. In addition, the confining region 124 can have a second conductivity type. The second conductivity type can be different from the first conductivity type. For instance, in some implementations, the confining region 124 is p-type. The confining region 124 can be doped with suitable dopants to form the second conductivity type. In the semiconductor device 200, the confining region 124 is on a surface 121 of the semiconductor structure 102 and does not extend into the semiconductor structure 102.

The channel region 122 can have a first thickness 123. Additionally or alternatively, the confining region 124 can have a second thickness 125. The first thickness 123 and the second thickness 125 may be similar, identical, or different. For instance, in some implementations, the channel region 122 and the confining region 124 have an identical thickness. Additionally or alternatively, in some implementations, the channel region 122 has a greater thickness than the confining region 124. Additionally or alternatively, in some implementations, the confining region 124 has a greater thickness than the channel region 122.

The first thickness 123 of the channel region 122 may be in a range of about 10 nm to about 500 nm, such as about 50 nm to about 250 nm, such as about 50 nm to about 100 nm. The second thickness 125 of the confining region 124 may be in a range of about 100 nm to about 1000 nm, such as about 150 nm to about 500 nm, such as about 200 nm to about 300 nm.

Those of ordinary skill in the art, using the disclosures provided herein, will understand that the height and width of the mesa structure 110 as well as the thicknesses of the channel region 122 and/or the confining region 124 may be determined based on the desired performance characteristics of the semiconductor device 100, such as the ability to provide a maximum current available through the channel region 122 while still maintaining an ability to modulate the current through a voltage applied to, for instance, a gate contact.

As illustrated in FIG. 2, the third contact 108 (e.g., gate contact) can be directly on at least one sidewall of the mesa structure 110. For instance, in some implementations, the third contact 108 can be on a first sidewall 114 of the mesa structure 110 and on a second sidewall 116 of the mesa structure 110. Additionally or alternatively, in some implementations, the third contact 108 can be on a top surface 115 of the mesa structure 110. In addition to being on the mesa structure 110, in some implementations, the third contact 108 can be on the semiconductor structure 102 in the recess 112. For instance, the third contact 108 can form a continuous contact across multiple mesa structures 110 through the sidewalls 114 and 116 and the top surface 115 of the mesa structures 110 and the recess 112. In this manner, applying a voltage to the third contact 108 can provide for each of the plurality of mesa structures 110 to produce the electrically conductive channel in the channel region 122. Because the third contact 108 (e.g., gate contact) is directly on the mesa structure 110, the semiconductor device 200 can be a MESFET type FinFET device.

FIG. 3 depicts a cross-sectional view of a semiconductor device 300 according to example embodiments of the present disclosure. The semiconductor device 300 includes various components discussed with reference to FIGS. 1 and 2, including the semiconductor structure 102, a plurality of mesa structures 110, a plurality of recesses 112 defined between the plurality of mesa structures 110, the third contact 108, the channel region 122, and the confining region 124. Except where otherwise indicated, these like reference numerals are used to represent like components, and description with respect to the semiconductor device 100 of FIG. 1 or semiconductor device 200 of FIG. 2 is equally intended to apply to the semiconductor device 300 of FIG. 3.

The semiconductor device 300 includes a dielectric layer 132 between the third 108 contact (e.g., gate contact) and the mesa structure 110 and/or the semiconductor structure 102. The dielectric layer 132 can additionally or alternatively reduce leakage from the channel region 122 into the third contact 108. The dielectric layer 132 can be formed of suitable material, such as silicon dioxide (SiO₂) or any other suitable dielectric material. The dielectric layer 132 may be much thinner than the third contact 108, having a thickness of, for example, between about 10 nanometers (nm) to about 50 nanometers. The dielectric layer 132 may be a gate oxide, such that the semiconductor device 300 is a MOSFET type FinFET device.

As illustrated in FIG. 3, the dielectric layer 132 can be on at least one sidewall of the mesa structure 110. For instance, in some implementations, the dielectric layer 132 can be on a first sidewall 114 of the mesa structure 110 and on a second sidewall 116 of the mesa structure 110. Additionally or alternatively, in some implementations, the dielectric layer 132 can be on a top surface 115 of the mesa structure 110. In addition to being on the mesa structure 110, in some implementations, the dielectric layer 132 can be on the semiconductor structure 102 in the recess 112. For instance, the dielectric layer 132 can form a continuous layer across multiple mesa structures 110 through the sidewalls 114 and 116 and the top surface 115 of the mesa structures 110 and the recess 112.

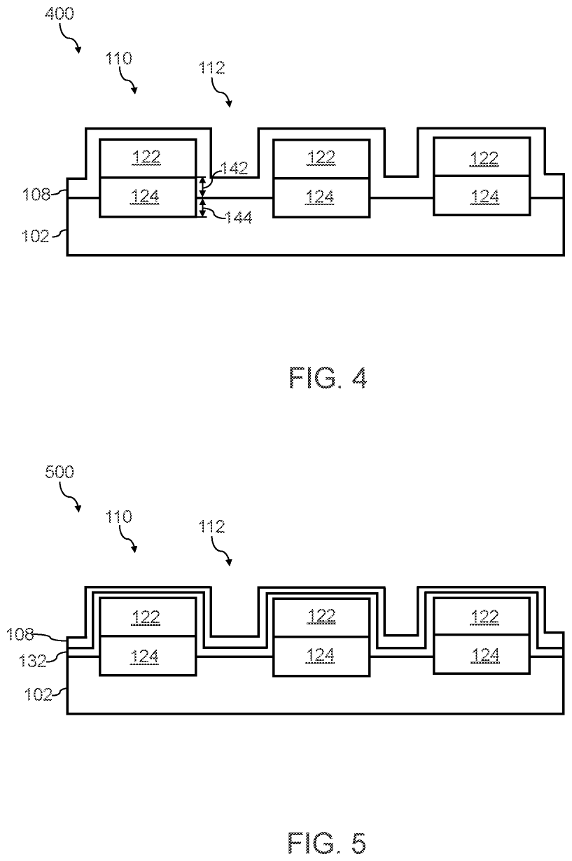

FIG. 4 depicts a cross-sectional view of a semiconductor device 400 according to example embodiments of the present disclosure. The semiconductor device 400 includes various components discussed with reference to FIGS. 1 and 2, including the semiconductor structure 102, a plurality of mesa structures 110, a plurality of recesses 112 defined between the plurality of mesa structures 110, the third contact 108, the channel region 122, and the confining region 124. Except where otherwise indicated, these like reference numerals are used to represent like components, and description with respect to the semiconductor device 100 of FIG. 1 or semiconductor device 200 of FIG. 2 is equally intended to apply to the semiconductor device 400 of FIG. 4.

The semiconductor device 400 includes a confining region 124 that is within the semiconductor structure 102 and in the mesa structure 110. For instance, the mesa structure 110 at least partially overlaps the confining region 124. The confining region 124 includes a first portion 142 that is above the semiconductor structure 102 and overlapped by the mesa structure 110, and a second portion 144 that extends into the semiconductor structure 102. Embedding a portion of the confining region 124 into the semiconductor structure 102 can reduce a three-dimensional profile of the semiconductor device 400.

FIG. 5 depicts a cross-sectional view of a semiconductor device 500 according to example embodiments of the present disclosure. The semiconductor device 500 includes various components discussed with reference to FIGS. 1 and 2, including the semiconductor structure 102, a plurality of mesa structures 110, a plurality of recesses 112 defined between the plurality of mesa structures 110, the third contact 108, the channel region 122, and the confining region 124. Except where otherwise indicated, these like reference numerals are used to represent like components, and description with respect to the semiconductor device 100 of FIG. 1 or semiconductor device 200 of FIG. 2 is equally intended to apply to the semiconductor device 500 of FIG. 5. In addition, the semiconductor device 500 further includes a confining region 124 that is within the semiconductor structure 102 and in the mesa structure 110, as discussed with respect to semiconductor device 400 of FIG. 4

The semiconductor device 500 further includes a dielectric layer 132 between the third 108 contact and the mesa structure 110 and/or the semiconductor structure 102. The dielectric layer 132 can provide improved electrical isolation between the third contact 108 and the mesa structure 110 and/or the semiconductor structure 102. For instance, the dielectric layer 132 can be between the third contact 108 and the channel region 122. The dielectric layer 132 can additionally or alternatively reduce leakage from the channel region 122 into the third contact 108. The dielectric layer 132 can be formed of suitable material, such as silicon dioxide (SiO₂) or any other suitable dielectric material. The dielectric layer 132 may be much thinner than the third contact 108, having a thickness of, for example, between about 10 nanometers (nm) to about 50 nanometers.

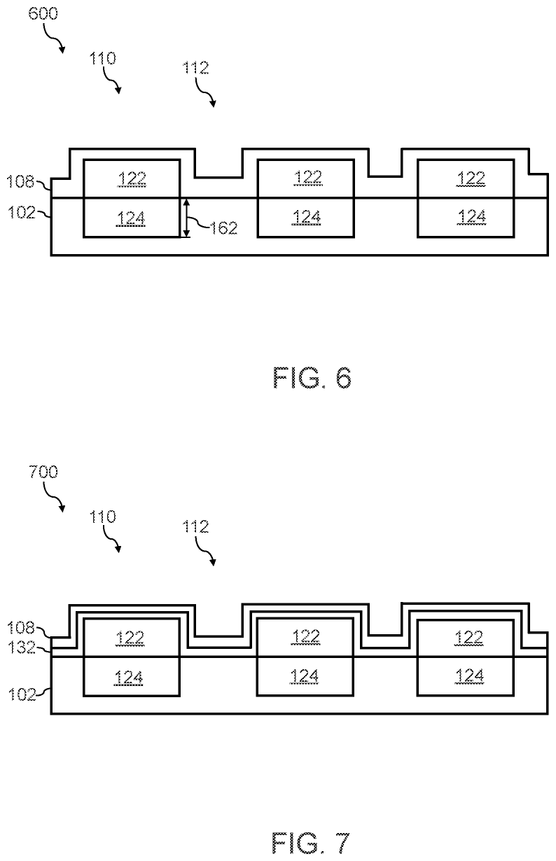

FIG. 6 depicts a cross-sectional view of a semiconductor device 600 according to example embodiments of the present disclosure. The semiconductor device 600 includes various components discussed with reference to FIGS. 1 and 2, including the semiconductor structure 102, a plurality of mesa structures 110, a plurality of recesses 112 defined between the plurality of mesa structures 110, the third contact 108, the channel region 122, and the confining region 124. Except where otherwise indicated, these like reference numerals are used to represent like components, and description with respect to the semiconductor device 100 of FIG. 1 or semiconductor device 200 of FIG. 2 is equally intended to apply to the semiconductor device 600 of FIG. 6.

The semiconductor device 600 includes a confining region 124 that is entirely within the semiconductor structure 102. For instance, the mesa structure 110 may entirely be the channel region 122. The confining region 124 may extend a depth 162 into the semiconductor structure 102 that is equal to the thickness 125 (FIG. 2) of the confining region. 124. The third gate contact 108 and the mesa structure 110 may not overlap the confining region 124 that is entirely within the semiconductor structure 102.

FIG. 7 depicts a cross-sectional view of a semiconductor device 700 according to example embodiments of the present disclosure. The semiconductor device 700 includes various components discussed with reference to FIGS. 1 and 2, including the semiconductor structure 102, a plurality of mesa structures 110, a plurality of recesses 112 defined between the plurality of mesa structures 110, the third contact 108, the channel region 122, and the confining region 124. Except where otherwise indicated, these like reference numerals are used to represent like components, and description with respect to the semiconductor device 100 of FIG. 1 or semiconductor device 200 of FIG. 2 is equally intended to apply to the semiconductor device 700 of FIG. 7. In addition, the semiconductor device 700 further includes a confining region 124 that is within the semiconductor structure 102, as discussed with respect to semiconductor device 600 of FIG. 6.

The semiconductor device 700 further includes a dielectric layer 132 between the third 108 contact and the mesa structure 110 and/or the semiconductor structure 102. The dielectric layer 132 can provide improved electrical isolation between the third contact 108 and the mesa structure 110 and/or the semiconductor structure 102. For instance, the dielectric layer 132 can be between the third contact 108 and the channel region 122. The dielectric layer 132 can additionally or alternatively reduce leakage from the channel region 122 into the third contact 108. The dielectric layer 132 can be formed of suitable material, such as silicon dioxide (SiO₂) or any other suitable dielectric material. The dielectric layer 132 may be much thinner than the third contact 108, having a thickness of, for example, between about 10 nanometers (nm) to about 50 nanometers.

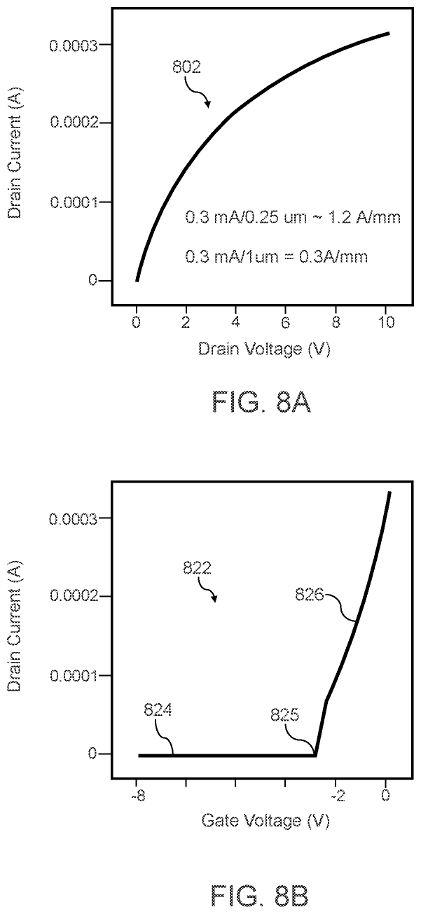

FIGS. 8A and 8B depict plots of response characteristics of an example semiconductor device according to example embodiments of the present disclosure. For instance, the semiconductor device may be the semiconductor device 100 of FIG. 1, or other suitable semiconductor device according to example embodiments of the present disclosure. In particular, FIG. 8A depicts a curve 802 of drain voltage versus drain current at a neutral gate voltage. As illustrated by curve 802, the drain current tends to increase with drain voltage in a quadratic manner under neutral gate voltage. In addition, FIG. 8B depicts a curve 822 of gate voltage versus drain current at a positive drain voltage. As illustrated by curve 822, the drain current remains around 0 amps over a first portion 824 at large negative gate voltages. The curve 822 transitions to a second portion 826 at inflection point 825. Over the second portion 826, the semiconductor device demonstrates a corresponding relationship between gate voltage and drain current, indicating a transition from an OFF state to an ON state at about −2V for the device.

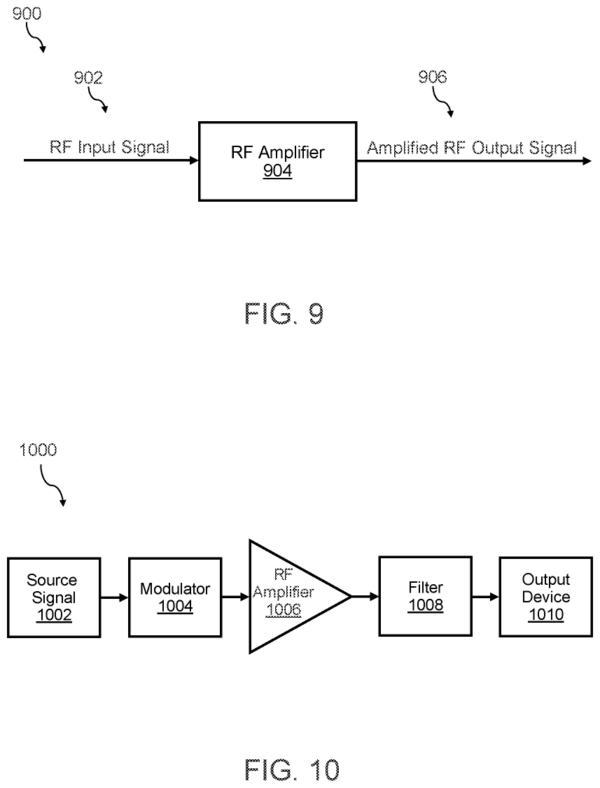

FIG. 9 depicts a block diagram of an example radiofrequency (RF) circuit 900 incorporating semiconductor devices according to example embodiments of the present disclosure. For instance, the RF circuit 900 can include an RF amplifier 904 configured to receive an RF input signal 902 and amplify the RF input signal 902 to produce an amplified RF output signal 906. According to example aspects of the present disclosure, the RF amplifier 904 can include one or more semiconductor devices discussed herein, such as the semiconductor devices of FIGS. 1-7. The RF amplifier circuit 900 may be associated with an operating frequency. For instance, the operating frequency may be in a range of about 10 GHz to about 40 GHz.

FIG. 10 depicts a block diagram of an example RF circuit 1000 incorporating semiconductor devices according to example embodiments of the present disclosure. The RF circuit 1000 can include a source signal 1002, such as an RF signal. The source signal 1002 can be provided to a modulator 1004, which is configured to modulate the source signal 1002 in accordance with an operating frequency to produce a modulated signal. For instance, the operating frequency may be in a range of about 10 GHz to about 40 GHz. The modulated signal can be provided to an RF amplifier 1006 configured to amplify the modulated signal to produce an amplified modulated signal. According to example aspects of the present disclosure, the RF amplifier 1006 can include one or more semiconductor devices discussed herein, such as the semiconductor devices of FIGS. 1-7. The amplified modulated signal can be provided to a filter 1008 configured to filter out undesired frequency components. The output signal from the filter 1008 can be provided to an output device 1010, such as an RF antenna or other suitable device.

One example aspect of the present disclosure is directed to a semiconductor device. The semiconductor device includes a semiconductor structure comprising silicon carbide. The semiconductor device further includes a mesa structure protruding in a first direction from the semiconductor structure, the mesa structure extending in a second direction between a first contact on the semiconductor structure and a second contact on the semiconductor structure. The semiconductor device further includes a channel region in the mesa structure. The semiconductor device further includes an electrically floating confining region, the electrically floating confining region in contact with the channel region in the mesa structure. The semiconductor device further includes a third contact on at least one sidewall of the mesa structure.

In some examples, the third contact is between the first contact and the second contact.

In some examples, the third contact is on a first sidewall of the mesa structure and on a second sidewall of the mesa structure.

In some examples, the third contact is a Schottky contact with the mesa structure.

In some examples, the semiconductor device further includes a dielectric layer between the third contact and the mesa structure.

In some examples, the mesa structure comprises silicon carbide.

In some examples, the semiconductor device comprises a plurality of mesa structures, each mesa structure separated from an adjacent mesa structure by a recess.

In some examples, the third contact is on the semiconductor structure in the recess.

In some examples, the channel region has a first conductivity type.

In some examples, the electrically floating confining region has a second conductivity type, wherein the electrically floating confining region is in the semiconductor structure, wherein the mesa structure at least partially overlaps the confining region.

In some examples, the electrically floating confining region is in the mesa structure.

In some examples, the electrically floating confining region is in the semiconductor structure and in the mesa structure.

In some examples, the channel region provides an electrically conductive channel between the first contact and the second contact based on a voltage applied to the third contact.

In some examples, the first contact and the second contact are each an ohmic contact with the semiconductor structure.

In some examples, the semiconductor structure comprises a semi-insulating silicon carbide substrate.

In some examples, the mesa structure is an epitaxial layer.

In some examples, the semiconductor device comprises a MESFET type FinFET device.

In some examples, the semiconductor device comprises a MOSFET type FinFET device.

In some examples, the semiconductor device is part of an RF amplifier circuit.

In some examples, the RF amplifier circuit is associated with an operating frequency in a range of about 10 GHz to about 40 GHz.

Another example aspect of the present disclosure is directed to a semiconductor device. The semiconductor device includes a semiconductor structure comprising silicon carbide. The semiconductor device further includes a source contact on the semiconductor structure. The semiconductor device further includes a drain contact on the semiconductor structure. The semiconductor device further includes a mesa structure protruding from the semiconductor structure, the mesa structure comprising silicon carbide, the mesa structure comprising a channel region and a confining region. The semiconductor device further includes a gate contact on the mesa structure.

In some examples, the channel region provides an electrically conductive channel between the source contact and the drain contact based on a voltage applied to the gate contact.

In some examples, the semiconductor device further includes a plurality of mesa structures protruding from the semiconductor structure, each of the plurality of mesa structures extending between the source contact and the drain contact; and a recess defined between the plurality of mesa structures.

In some examples, the gate contact is on the semiconductor structure in the recess.

In some examples, the gate contact is between the source contact and the drain contact.

In some examples, the gate contact is on a top surface of the mesa structure and on a sidewall of the mesa structure.

In some examples, the gate contact is a Schottky contact with the mesa structure.

In some examples, the semiconductor device further includes a dielectric layer between the gate contact and the mesa structure.

In some examples, the channel region has a first conductivity type, wherein the confining region has a second conductivity type.

In some examples, the confining region is a p-type region and the channel region is an n-type region.

In some examples, the confining region is electrically floating.

In some examples, the source contact and the drain contact are each an ohmic contact with the semiconductor structure.

In some examples, the gate contact is located a first distance from the source contact and a second distance from the drain contact.

In some examples, the first distance is different than the second distance.

In some examples, the first distance is in a range of about 0.3 μm to about 0.5 μm.

In some examples, the second distance is in a range of about 0.1 μm to about 0.3 μm.

In some examples, the mesa structure has a width dimension, the width dimension being generally perpendicular to a direction of the mesa structure between the source contact and the drain contact in a plane that is generally parallel to the semiconductor structure, the width dimension being in a range of about 0.15 μm to about 0.35 μm.

In some examples, the mesa structure has a height dimension, the height dimension being generally perpendicular to the semiconductor structure, the height dimension being in a range of about 50 nm to about 1000 nm.

In some examples, the semiconductor structure comprises a semi-insulating silicon carbide substrate.

In some examples, the mesa structure is an epitaxial layer.

In some examples, the semiconductor device comprises a MESFET.

In some examples, the semiconductor device comprises a MOSFET.

Another example aspect of the present disclosure is directed to a lateral transistor device. The lateral transistor device includes a semiconductor structure comprising silicon carbide. The lateral transistor device further includes a mesa structure protruding from the semiconductor structure, the mesa structure comprising silicon carbide, the mesa structure comprising a channel region. The lateral transistor device further includes a gate contact on a top surface of the mesa structure and a sidewall of the mesa structure.

In some examples, the lateral transistor device further includes a source contact and a drain contact on the semiconductor structure, the mesa structure extending between the source contact and the drain contact.

In some examples, the gate contact is between the source contact and the drain contact.

In some examples, the gate contact is a Schottky contact with the mesa structure.

In some examples, the lateral transistor device further includes a dielectric layer between the gate contact and the mesa structure.

In some examples, the mesa structure provides an electrically conductive channel based on a voltage applied to the gate contact.

In some examples, the mesa structure comprises silicon carbide.

In some examples, the mesa structure comprises a first region of a first conductivity type, wherein the semiconductor structure comprises a second region of a second conductivity type, wherein the mesa structure at least partially overlaps the second region.

In some examples, the mesa structure comprises a first region of a first conductivity type and a second region of a second conductivity type on the first region.

In some examples, the second region is electrically floating.

In some examples, the gate contact is located a first distance from the source contact and a second distance from the drain contact.

In some examples, the first distance is in a range of about 0.3 μm to about 0.5 μm.

In some examples, the second distance is in a range of about 0.1 μm to about 0.3 μm.

In some examples, the mesa structure has a width dimension, the width dimension being generally perpendicular to a direction of the mesa structure between the source contact and the drain contact in a plane that is generally parallel to the semiconductor structure, the width dimension being in a range of about 0.15 μm to about 0.35 μm.

In some examples, the mesa structure has a height dimension, the height dimension being generally perpendicular to the semiconductor structure, the height dimension being in a range of about 50 nm to about 1000 nm.

In some examples, the semiconductor structure comprises a semi-insulating silicon carbide substrate.

In some examples, the mesa structure is an epitaxial layer.

In some examples, the lateral transistor device comprises a MESFET.

In some examples, the lateral transistor device comprises a MOSFET.

In some examples, the lateral transistor device is part of an RF amplifier circuit.

In some examples, the RF amplifier circuit is associated with an operating frequency in a range of about 10 GHz to about 40 GHz.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a semiconductor structure comprising silicon carbide;
a mesa structure protruding in a first direction from the semiconductor structure, the mesa structure extending in a second direction between a first contact on the semiconductor structure and a second contact on the semiconductor structure;
a channel region in the mesa structure;
an electrically floating confining region, the electrically floating confining region in contact with the channel region in the mesa structure; and
a third contact on at least one sidewall of the mesa structure.

2. The semiconductor device of claim 1, wherein the third contact is between the first contact and the second contact.

3. The semiconductor device of claim 1, wherein the third contact is on a first sidewall of the mesa structure and on a second sidewall of the mesa structure.

4. The semiconductor device of claim 1, wherein the third contact is a Schottky contact with the mesa structure.

5. The semiconductor device of claim 1, further comprising a dielectric layer between the third contact and the mesa structure.

6. The semiconductor device of claim 1, wherein the mesa structure comprises silicon carbide.

7. The semiconductor device of claim 1, wherein the semiconductor device comprises a plurality of mesa structures, each mesa structure separated from an adjacent mesa structure by a recess.

8. The semiconductor device of claim 7, wherein the third contact is on the semiconductor structure in the recess.

9. The semiconductor device of claim 1, wherein the channel region has a first conductivity type.

10. The semiconductor device of claim 9, wherein the electrically floating confining region has a second conductivity type, wherein the electrically floating confining region is in the semiconductor structure, wherein the mesa structure at least partially overlaps the confining region.

11. The semiconductor device of claim 1, wherein the electrically floating confining region is in the mesa structure.

12. The semiconductor device of claim 1, wherein the electrically floating confining region is in the semiconductor structure and in the mesa structure.

13. The semiconductor device of claim 1, wherein the channel region provides an electrically conductive channel between the first contact and the second contact based on a voltage applied to the third contact.

14. (canceled)

15. The semiconductor device of claim 1, wherein the semiconductor structure comprises a semi-insulating silicon carbide substrate.

16. (canceled)

17. The semiconductor device of claim 1, wherein the semiconductor device comprises a MESFET type FinFET device.

18. The semiconductor device of claim 1, wherein the semiconductor device comprises a MOSFET type FinFET device.

19. The semiconductor device of claim 1, wherein the semiconductor device is part of an RF amplifier circuit.

20. The semiconductor device of claim 19, wherein the RF amplifier circuit is associated with an operating frequency in a range of about 10 GHz to about 40 GHz.

21. A semiconductor device, comprising:
a semiconductor structure comprising silicon carbide;
a source contact on the semiconductor structure;
a drain contact on the semiconductor structure;
a mesa structure protruding from the semiconductor structure, the mesa structure comprising silicon carbide, the mesa structure comprising a channel region and a confining region; and
a gate contact on the mesa structure.

22.-42. (canceled)

43. A lateral transistor device, comprising:
a semiconductor structure comprising silicon carbide;
a mesa structure protruding from the semiconductor structure, the mesa structure comprising silicon carbide, the mesa structure comprising a channel region; and
a gate contact on a top surface of the mesa structure and a sidewall of the mesa structure.

44.-63. (canceled)
